(19) United States
(12) Patent Application Publication
(10) Pub. No.: US 2026/0353576 A1
(43) Pub. Date: Nov. 5, 2026

(54) ELECTRONIC DEVICE

(71) Applicant: Samsung Display Co., LTD., Yongin-si (KR)

(72) Inventor: EUNAH KIM, Yongin-si (KR)

(21) Appl. No.: 19/430,977

(22) Filed: Dec. 23, 2025

(30) Foreign Application Priority Data
May 2, 2025 (KR) 10-2025-0058058

(51) Int. Cl. H05K 5/02

(52) U.S. Cl. CPC H05K 5/0217

(57) ABSTRACT

An electronic device includes a display device including a first portion, a second portion, and a dummy portion disposed between the first portion and the second portion and a case that accommodates the display device and has openings defined therein to expose a first display area of the first portion and a second display area of the second portion to the outside. The dummy portion is bent from the first portion and the second portion, the first portion is folded and unfolded, and the second portion is disposed in a higher position than a position of the first portion when the first portion is unfolded.

This application claims priority to Korean Patent Application No. 10-2025-0058058, filed on May 02, 2025, and all the benefits accruing therefrom under 35 U.S.C. §119, the content of which in its entirety is herein incorporated by reference.

### BACKGROUND

### 1. FIELD

Embodiments of the disclosure described herein relate to an electronic device.

### 2. DESCRIPTION OF THE RELATED ART

Electronic devices, such as a smart phone, a digital camera, a notebook computer, a car navigation device, and a smart television, which provide an image to a user include a display device for displaying the image. The display device generates the image and provides the image to the user through a display surface.

Recently, with the development of display device technology, various types of display devices are being developed. For example, various flexible display devices capable of being transformed into a curved shape, folded, or rolled are being developed. The flexible display devices having shapes capable of being transformed in various ways are easy to carry and improve user convenience.

Among the flexible display devices, a foldable display device includes a display module that is folded about a folding axis extending in one direction. The display module is folded or unfolded about the folding axis. The display module includes a folding area that is bent in a folding operation. The folding area may be bent to have a predetermined radius of curvature.

The foldable display device includes a camera disposed under or over the display module to take a photo or image. The camera may protrude outward from the case. The protruding camera may be vulnerable to impacts such as a drop impact, and due to the protruding camera, there may be a limitation in product design. Therefore, the development of an electronic device including a camera that does not protrude outward from the case is desired.

### SUMMARY

Embodiments of the disclosure provide an electronic device for reducing manufacturing costs by implementing a main area and a sub-area with a single display panel.

In addition, embodiments of the disclosure provide an electronic device for protecting a functional element by placing the functional element within a case such that the functional element does not protrude outward from the case.

In an embodiment, an electronic device includes a display device including a first portion, a second portion, and a dummy portion disposed between the first portion and the second portion and a case that accommodates the display device and defines openings therein to expose a first display area of the first portion and a second display area of the second portion to the outside. The dummy portion is bent from the first portion and the second portion, the first portion is folded and unfolded, and the second portion is disposed in a higher position than a position of the first portion when the first portion is unfolded.

In an embodiment, an electronic device includes a display device including a first portion, a second portion, and a dummy portion disposed between the first portion and the second portion and a case that accommodates the display device and defines openings therein to expose a first display area of the first portion and a second display area of the second portion to the outside. The case includes a first case portion that accommodates the first portion and defines a first opening therein to expose the first display area and that is folded and unfolded, a second case portion that accommodates the second portion and defines a second opening therein to expose the second display area, and a third case portion that accommodates the dummy portion and that is disposed between the first case portion and the second case portion, and the dummy portion is closed by the third case portion.

### BRIEF DESCRIPTION OF THE DRAWINGS

The above and other embodiments, advantages and features of the disclosure will become apparent by describing in detail embodiments thereof with reference to the accompanying drawings.

FIG. 1 is a block diagram of an embodiment of an electronic device of the disclosure.

FIG. 2 illustrates schematic views of embodiments of electronic devices.

FIG. 3 is a perspective view illustrating an embodiment of an unfolded state of an electronic device of the disclosure.

FIG. 4 is a perspective view illustrating a folded state of the electronic device illustrated in FIG. 3.

FIG. 5 is an exploded perspective view of the electronic device illustrated in FIG. 3.

FIG. 6 is a plan view of a display panel used in the electronic device illustrated in FIG. 5.

FIG. 7 is a view illustrating a cross-section of a display module used in a display device illustrated in FIG. 5.

FIG. 8 is a view more specifically illustrating a cross-section of the display panel and an input sensing part corresponding to one pixel illustrated in FIG. 6.

FIG. 9 is a cross-sectional view of the display device corresponding to line I-I’ illustrated in FIG. 6.

FIG. 10 is a perspective view of a first support plate illustrated in FIG. 9.

FIG. 11 is an enlarged plan view of area AA illustrated in FIG. 10.

FIG. 12 is a view illustrating a folded state of the display device illustrated in FIG. 9.

FIG. 13 is a cross-sectional view of the electronic device corresponding to line II-II’ illustrated in FIG. 3.

FIG. 14 is a cross-sectional view of the electronic device corresponding to line III-III’ illustrated in FIG. 4.

### DETAILED DESCRIPTION

In this specification, when a component (or, an area, a layer, a part, etc.) is also referred to as being “on”, “connected to” or “coupled to” another component, this means that the component may be directly on, connected to, or coupled to the other component or a third component may be therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, or the like may be used to describe various components, but the components should not be limited by the terms. The terms may be used only for distinguishing one component, part, area, layer, or portion from other components, parts, areas, layers, or portions. For example, without departing the scope and scope of the disclosure, a first component, a first part, a first area, a first layer, or a first portion may be also referred to as a second component, a second part, a second area, a second layer, or a second portion, and similarly, the second component, the second part, the second area, the second layer, or the second portion may also be also referred to as the first component, the first part, the first area, the first layer, or the first portion. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Hereinafter, embodiments of the disclosure will be described with reference to the accompanying drawings.

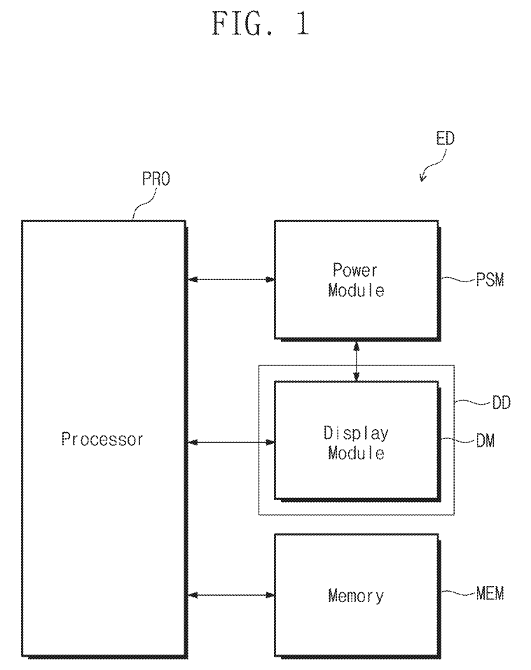

FIG. 1 is a block diagram of an embodiment of an electronic device of the disclosure.

Referring to FIG. 1, the electronic device ED in an embodiment may include a display device DD that provides an image to a user and may further include modules or devices having other additional functions, in addition to the display device DD. The electronic device ED in an embodiment may include a display module DM, a processor PRO, a memory MEM, and a power module PSM, and the display device DD may include the display module DM.

The processor PRO may include at least one of a central processing unit (“CPU”), an application processor (“AP”), a graphic processing unit (“GPU”), a communication processor (“CP”), an image signal processor (“ISP”), and a controller.

The processor PRO may process an image signal and may provide the processed image signal to the display device DD. The display device DD may receive the image signal from the processor PRO and may provide an image corresponding to the image signal to the user.

The processor PRO may be electrically connected to the display module DM of the display device DD through a flexible circuit board and a connector. The display module DM may display an image based on data received from the processor PRO.

In an embodiment, the processor PRO may be divided into two or more parts from a functional or structural point of view. In an embodiment, the processor PRO may include a main processor in the form of a first driver IC that includes a central processing unit and an auxiliary processor in the form of a second driver IC that includes a controller that receives an image signal from the main processor and processes the image signal according to the interface specifications of the display module DM, for example.

Data information desired for operation of the processor PRO or the display module DM may be stored in the memory MEM. When the processor PRO executes an application stored in the memory MEM, an image signal and/or an input control signal may be transferred to the display module DM, and the display module DM may process the provided signal and may output image information through a display screen.

The power module PSM may include a power supply module such as a power adapter or a battery device and a power conversion module that converts power supplied by the power supply module and generates power desired for operation of the electronic device ED.

At least one of the components of the electronic device ED described above may be included in the display device DD according to the above-described embodiments. In addition, some of the separate modules functionally included in one module may be included in the display device DD, and remaining (the other) separate modules may be provided separately from the display device DD.

In an embodiment, the display device DD may include the display module DM, and the processor PRO, the memory MEM, and the power module PSM may be provided in the form of other devices in the electronic device ED rather than the display device DD, for example.

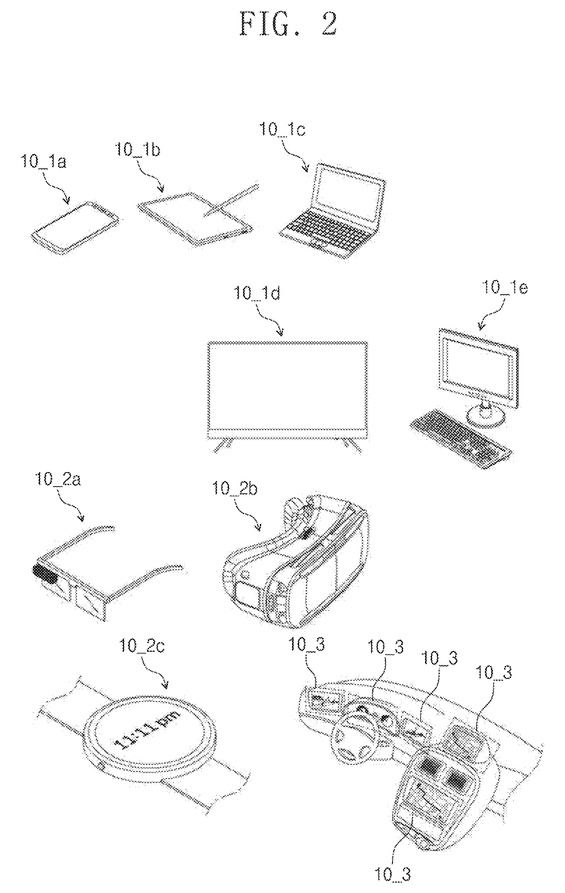

FIG. 2 illustrates schematic views of embodiments of electronic devices.

Referring to FIG. 2, the display device DD (described below) and a case CAS (described below) in an embodiment of the disclosure may be applied to various electronic devices. In an embodiment, the various electronic devices to which the display device DD (described below) and the case CAS (described below) in an embodiment are applied may include electronic devices for displaying images, such as a smart phone 10_1a, a tablet PC 10_1b, a laptop computer 10_1c, a television (“TV”) 10_1d, and a desk monitor 10_1e, for example.

Furthermore, the various electronic devices to which the display device DD (described below) and the case CAS (described below) in an embodiment are applied may include wearable electronic devices, such as smart glasses 10_2a, a head mounted display 10_2b, and a smart watch 10_2c. In addition, the various electronic devices to which the display device DD (described below) and the case CAS (described below) in an embodiment are applied may include vehicle electronic devices 10_3, such as center information displays (“CID”) disposed on an instrument panel, a center fascia, and a dashboard of a vehicle and a room mirror display.

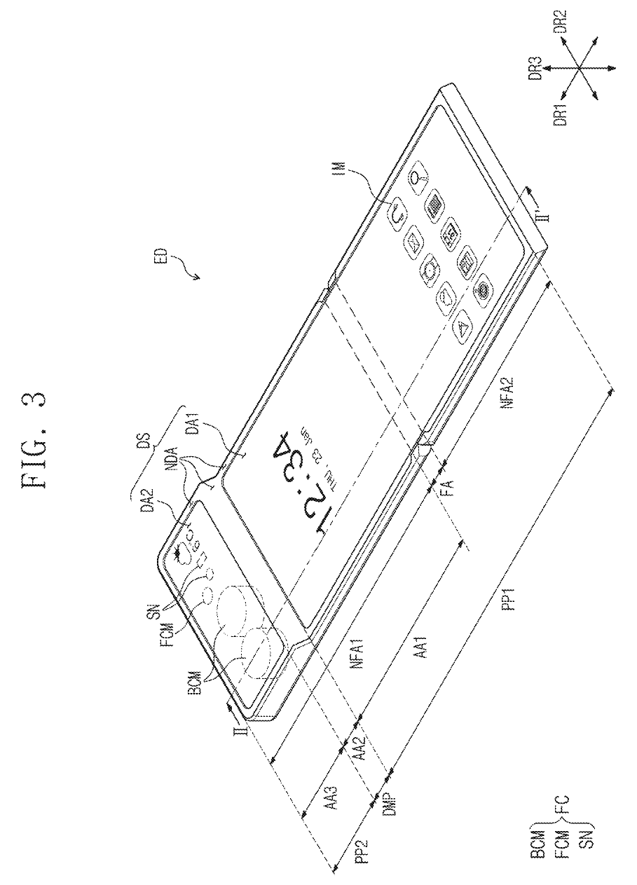

FIG. 3 is a perspective view illustrating an embodiment of an unfolded state of an electronic device of the disclosure.

Referring to FIG. 3, the electronic device ED in an embodiment of the disclosure may have long sides extending parallel to a first direction DR1 and short sides extending parallel to a second direction DR2 crossing the first direction DR1.

Hereinafter, a direction substantially perpendicular to a plane defined by the first direction DR1 and the second direction DR2 is defined as a third direction DR3. The expression “when viewed from above the plane” used herein may mean that it is viewed in the third direction DR3. In addition, the term “overlap” used herein may indicate a state in which components are disposed to overlap each other when viewed from above the plane.

The electronic device ED may include a folding area FA and a plurality of non-folding areas NFA1 and NFA2 next (adjacent) to the folding area FA. The non-folding areas NFA1 and NFA2 may include the first non-folding area NFA1 and the second non-folding area NFA2. The folding area FA may be disposed between the first non-folding area NFA1 and the second non-folding area NFA2. The first non-folding area NFA1, the folding area FA, and the second non-folding area NFA2 may be arranged in the first direction DR1. The first non-folding area NFA1 may include a first area AA1, a second area AA2, and a third area AA3. The second area AA2 may be disposed between the first area AA1 and the third area AA3. The first area AA1, the second area AA2, and the third area AA3 may be arranged in the first direction DR1.

Although one folding area FA and two non-folding areas NFA1 and NFA2 are illustrated in an embodiment, the numbers of folding areas FA and non-folding areas NFA1 and NFA2 are not limited thereto. In an embodiment, the electronic device ED may include more than two non-folding areas and a plurality of folding areas disposed between the non-folding areas, for example.

The electronic device ED may include a first portion PP1, a dummy portion DMP next (adjacent) to the first portion PP1, and a second portion PP2 next (adjacent) to the dummy portion DMP. The dummy portion DMP may be disposed between the first portion PP1 and the second portion PP2. The first portion PP1, the dummy portion DMP, and the second portion PP2 may be arranged in the first direction DR1.

The first portion PP1 may be defined by the first area AA1 of the first non-folding area NFA1 that extends from the folding area FA, the folding area FA, and the second non-folding area NFA2. The dummy portion DMP may be defined by the second area AA2 of the first non-folding area NFA1 that is next (adjacent) to the first portion PP1. The second portion PP2 may be defined by the third area AA3 of the first non-folding area NFA1 that is next (adjacent) to the dummy portion DMP.

The first portion PP1 may extend longer in the first direction DR1 than in the second direction DR2. The dummy portion DMP may extend longer in the second direction DR2 than in the first direction DR1. The second portion PP2 may extend longer in the second direction DR2 than in the first direction DR1.

The dummy portion DMP may extend from the first portion PP1 to the second portion PP2. The upper surface of the dummy portion DMP may have an inclined surface. In an embodiment, the height of the upper surface of the dummy portion DMP may be gradually increased toward the second portion PP2 from the first portion PP1, for example.

A display surface DS may be defined on the upper surface of the electronic device ED. Generated Images IM may be provided to the user through the display surface DS. The display surface DS may include a first display area DA1, a second display area DA2, and a non-display area NDA around the first display area DA1 and the second display area DA2.

Specifically, the upper surface of the first portion PP1 may include the first display area DA1 and the non-display area NDA around the first display area DA1. The upper surface of the second portion PP2 may include the second display area DA2 and the non-display area NDA around the second display area DA2. The upper surface of the dummy portion DMP may include the non-display area NDA. The non-display area NDA of the first portion PP1, the non-display area NDA of the second portion PP2, and the non-display area NDA of the dummy portion DMP may be continuously defined. The non-display area NDA may substantially be a portion where the case CAS to be described below is disposed.

The first display area DA1 and the second display area DA2 may have a plane defined by the first direction DR1 and the second direction DR2. The first display area DA1 and the second display area DA2 may be separated from each other by the dummy portion DMP.

The first display area DA1 and the second display area DA2 may display an image, and the non-display area NDA may not display an image. The first display area DA1 and the second display area DA2 may display separate images, respectively. The non-display area NDA may define the border of the electronic device ED that surrounds the first display area DA1 and the second display area DA2 and that is printed in a predetermined color.

In an embodiment of the disclosure, e.g., the first display area DA1 may be defined as a main display area. In addition, the second display area DA2 may be defined as a sub-display area.

The electronic device ED may include functional elements FC. In an embodiment, the second portion PP2 of the electronic device ED may include the functional elements FC, for example. The functional elements FC may include a plurality of sensors having a sensing function and a plurality of cameras having a photographing function. In an embodiment, the functional elements FC may include two rear cameras BCM, one front camera FCM, and sensors SN, for example. The rear cameras BCM, the front camera FCM, and the sensors SN may be disposed in the third area AA3 of the first non-folding area NFA1. When viewed from above the plane, the rear cameras BCM, the front camera FCM, and the sensors SN may be disposed under the second display area DA2 to overlap the second display area DA2.

The sensors SN may be, e.g., proximity illuminance sensors. However, the type of sensors SN is not limited thereto. The rear cameras BCM and the front camera FCM may take an external image.

In FIG. 3, e.g., the electronic device ED is illustrated as a smart phone. This may be the smart phone 10_1a illustrated in FIG. 2. However, without being limited thereto, the electronic device ED may include various electronic devices. In an embodiment, the electronic device ED may include large electronic devices such as a television, a monitor, and a billboard, for example. In an alternative embodiment, the electronic device ED may include small and medium-sized electronic devices such as a personal computer, a notebook computer, a car navigation device, a game machine, a tablet computer, and a camera.

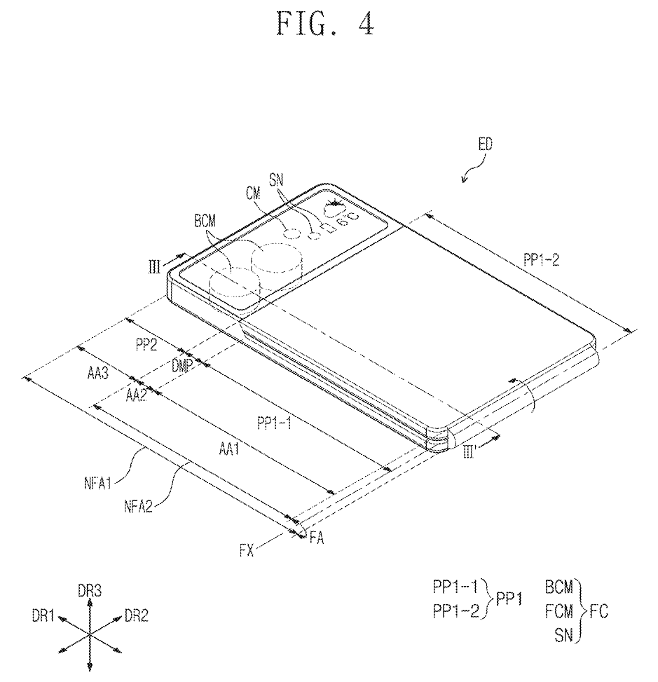

FIG. 4 is a perspective view illustrating a folded state of the electronic device illustrated in FIG. 3.

Referring to FIGS. 3 and 4, the electronic device ED may be a flexible electronic device. In an embodiment, the electronic device ED may be a foldable electronic device that is folded or unfolded, for example. In an embodiment, the folding area FA may be bent about a folding axis FX parallel to the second direction DR2 so that the electronic device ED may be folded, for example. The folding axis FX may be defined as a short axis parallel to the short sides of the electronic device ED.

The first portion PP1 may be folded when the electronic device ED is folded. In this case, the first area AA1 and the second area AA2 of the first non-folding area NFA1 may face the second non-folding area NFA2. The first portion PP1 may be folded in an in-folding manner such that the first display area DA1 is not exposed to the outside. When the first portion PP1 is folded, the second display area DA2 may be exposed to the outside. A predetermined image may be provided to the user through the second display area DA2. When the first portion PP1 is folded, one side of the first portion PP1 may face the dummy portion DMP. The first portion PP1 may include a first-first portion PP1-1 and a first-second portion PP1-2 next (adjacent) to the first-first portion PP1-1. The first-first portion PP1-1 and the first-second portion PP1-2 may be distinguished from each other based on the folding axis FX. When the first portion PP1 is folded, the first-first portion PP1-1 and the first-second portion PP1-2 may face each other. Accordingly, when the first portion PP1 is folded in an in-folding manner, the first-second portion PP1-2 may be disposed on the upper surface of the first-first portion PP1-1. However, embodiments of the disclosure are not limited thereto. In an embodiment, the electronic device ED may be folded about the folding axis FX in an out-folding manner such that the first display area DA1 is exposed to the outside, for example.

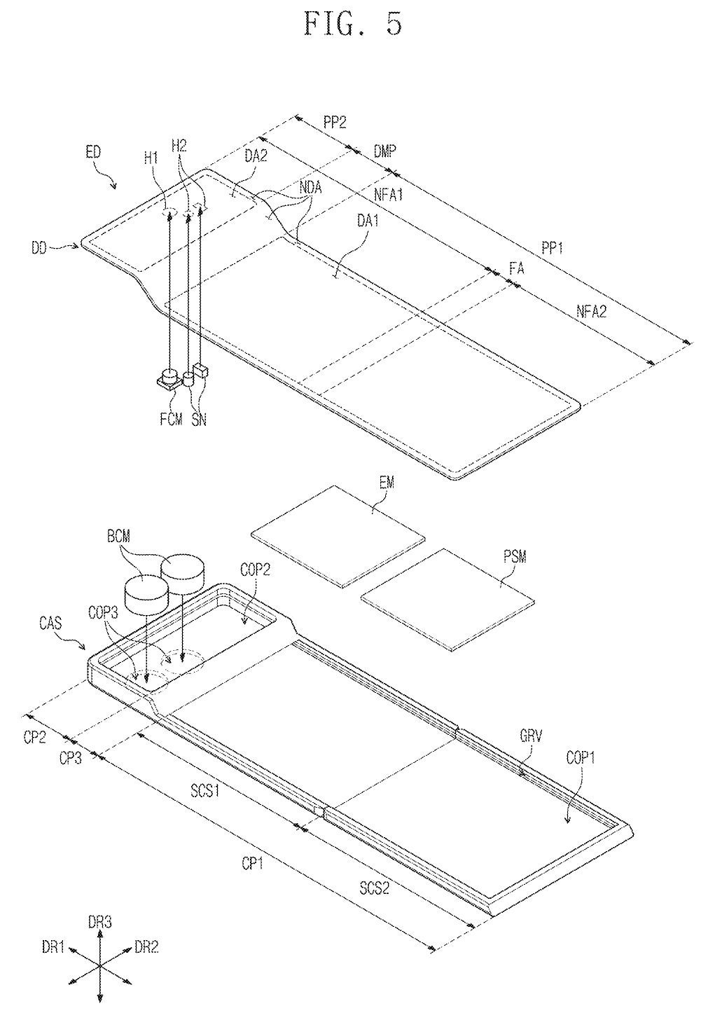

FIG. 5 is an exploded perspective view of the electronic device illustrated in FIG. 3.

Referring to FIG. 5, the electronic device ED may include the display device DD, the plurality of functional elements FC, an electronic module EM, the power module PSM, and the case CAS. The functional elements FC may include the rear cameras BCM, the front camera FCM, and the sensors SN.

The display device DD may have a first hole H1 and second holes H2 defined therein. The front camera FCM may be disposed in the first hole H1, and the sensors SN may be disposed in the second holes H2. However, the number of holes and the functional elements disposed therein are not limited thereto and may be provided in various combinations.

The display device DD may include a first portion PP1, a second portion PP2, and a dummy portion DMP disposed between the first portion PP1 and the second portion PP2. The first portion PP1, the second portion PP2, and the dummy portion DMP of the display device DD may correspond to the first portion PP1, the second portion PP2, and the dummy portion DMP of the electronic device ED, respectively, which have been described above, and the same reference numerals are used and illustrated for convenience of description.

The dummy portion DMP may be bent from the first portion PP1 and the second portion PP2. Since the dummy portion DMP is bent, the second portion PP2 may be disposed in a higher position than a position of the first portion PP1 when the unfolded display device DD is viewed in the second direction DR2.

When viewed from above the plane, the area of the first portion PP1 may be greater than the area of the second portion PP2. When viewed from above the plane, the area of the dummy portion DMP may be smaller than the area of the second portion PP2.

The upper surface of the display device DD may include a first display area DA1, a second display area DA2, and a non-display area NDA, like that of the electronic device ED described above. Specifically, the upper surface of the first portion PP1 may include the first display area DA1 and the non-display area NDA around the first display area DA1. The upper surface of the second portion PP2 may include the second display area DA2 and the non-display area NDA around the second display area DA2. The upper surface of the dummy portion DMP may include the non-display area NDA.

The electronic module EM and the power module PSM may be disposed under the display device DD. Although not illustrated, the electronic module EM and the power module PSM may be connected with each other through a flexible printed circuit board (“FPCB”). The electronic module EM may control operation of the display device DD. The power module PSM may supply power to the display device DD. The electronic module EM may include the above-described processor PRO.

The functional elements FC may be disposed under the display device DD. In an embodiment, the functional elements FC may be disposed under the second portion PP2, for example.

The display device DD, the functional elements FC, the electronic module EM, and the power module PSM may be accommodated in the case CAS. The case CAS may include a first case portion CP1, a second case portion CP2, and a third case portion CP3. The third case portion CP3 may be disposed between the first case portion CP1 and the second case portion CP2. The first case portion CP1, the third case portion CP3, and the second case portion CP2 may be arranged in the first direction DR1.

A first opening COP1 may be defined in the first case portion CP1 so as to be open toward the front side of the first case portion CP1. The first display area DA1 may be exposed toward the front side through the first opening COP1. A second opening COP2 may be defined in the second case portion CP2 so as to be open toward the front side of the second case portion CP2. The second display area DA2 may be exposed toward the front side through the second opening COP2. Third openings COP3 may be defined in the second case portion CP2 so as to be open toward the rear side of the second case portion CP2. The rear cameras BCM may be exposed to the outside through the third openings COP3.

The non-display area NDA of the display device DD may be accommodated in the case CAS. In an embodiment, the non-display area NDA may be disposed in grooves GRV defined on the inner surfaces of the first case portion CP1 and the second case portion CP2 that define the first opening COP1 and the second opening COP2 and in the third case portion CP3, for example. The third case portion CP3 may close the dummy portion DMP when the display device DD is accommodated in the case CAS.

The first case portion CP1 may include a first sub-case portion SCS1 and a second sub-case portion SCS2 to fold the first portion PP1. The first sub-case portion SCS1 and the second sub-case portion SCS2 may be arranged in the first direction DR1. The first opening COP1 may be continuously defined in the first sub-case portion SCS1 and the second sub-case portion SCS2.

When viewed from above the plane, a portion of the first sub-case portion SCS1, the second case portion CP2, and the third case portion CP3 may overlap the first non-folding area NFA1. When viewed from above the plane, a portion of the second sub-case portion SCS2 may overlap the second non-folding area NFA2. When viewed from above the plane, a portion of the first sub-case portion SCS1 and a portion of the second sub-case portion SCS2 may overlap the folding area FA. When viewed from above the plane, the first portion PP1 may overlap the first case portion CP1. The first portion PP1 may be accommodated in the first case portion CP1. When viewed from above the plane, the second portion PP2 may overlap the second case portion CP2. The second portion PP2 may be accommodated in the second case portion CP2. When viewed from above the plane, the dummy portion DMP may overlap the third case portion CP3. The dummy portion DMP may be accommodated in the third case portion CP3.

The first sub-case portion SCS1 may be separated from the second sub-case portion SCS2. The third case portion CP3 may extend from the first sub-case portion SCS1 and may be integrally formed (or unitary) with the first sub-case portion SCS1. The second case portion CP2 may extend from the third case portion CP3 and may be integrally formed (or unitary) with the third case portion CP3.

In an embodiment of the disclosure, the functional elements FC may not protrude outward from the lower surface of the second case portion CP2. Specifically, the space defined in the second case portion CP2 may sufficiently accommodate the rear cameras BCM, and thus the rear cameras BCM may not protrude outward from the lower surface of the second case portion CP2.

The upper surface of the third case portion CP3 may have an inclined surface. Specifically, the height of the inclined surface may be gradually increased toward the second case portion CP2 from the first case portion CP1.

The case CAS may protect the display device DD, the rear cameras BCM, the front camera FCM, the sensors SN, the electronic module EM, and the power module PSM.

Hereinafter, a “thickness” used herein may be defined as a numerical value measured in the third direction DR3. A “width” used herein may be defined as a numerical value measured in a horizontal direction (e.g., the first direction DR1 or the second direction DR2).

Although not illustrated, the electronic device ED may further include a hinge structure connected to the first sub-case portion SCS1 and the second sub-case portion SCS2 to control a folding operation of the electronic device ED.

Referring to FIGS. 4 and 5, the folding axis FX may be disposed between the first sub-case portion SCS1 and the second sub-case portion SCS2. The folding axis FX may be defined in a direction parallel to the second direction DR2. The first portion PP1 and the first case portion CP1 may be folded and unfolded about the folding axis FX. When viewed in a direction parallel to the folding axis FX, the thickness of the side surface of the second case portion CP2 may be greater than the thickness of the side surface of the first case portion CP1.

Referring to FIGS. 4 and 5, the upper surface of the third case portion CP3 may have an inclined surface. In addition, a short-side border of the first case portion CP1 parallel to the second direction DR2 (hereinafter, defined as one side of the first case portion CP1) may have an inclined surface. When the first case portion CP1 is folded, the one side of the first case portion CP1 may face the inclined surface of the upper surface of the third case portion CP3.

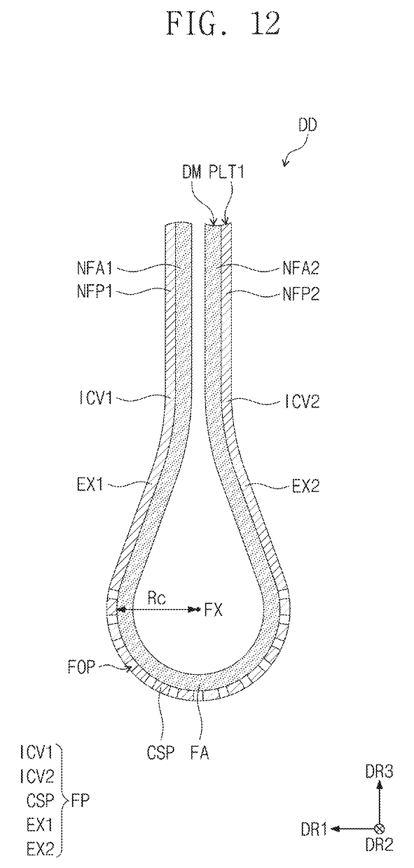

Although not illustrated in FIG. 5, the display device DD may be folded in a dumbbell shape, and this shape will be illustrated in detail in FIG. 12.

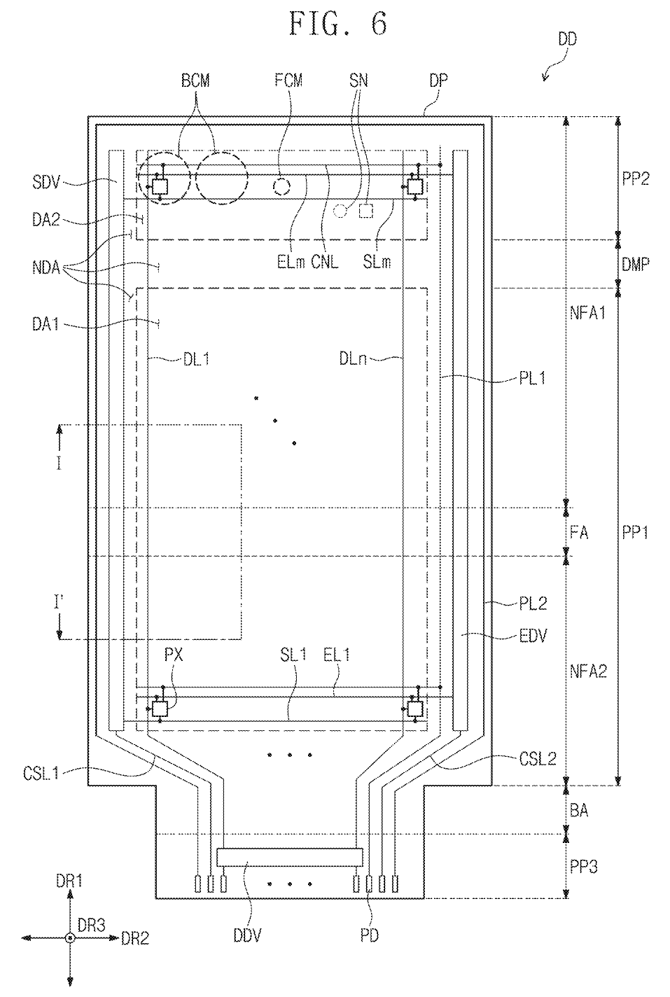

FIG. 6 is a plan view of a display panel used in the electronic device illustrated in FIG. 5.

Referring to FIG. 6, the display device DD may include the display panel DP, a scan driver SDV, a data driver DDV, and a light emission driver EDV.

The display panel DP in an embodiment of the disclosure may be an emissive display panel. In an embodiment, the display panel DP may be an organic light-emitting display panel or an inorganic light-emitting display panel, for example. A light-emitting layer of the organic light-emitting display panel may include an organic luminescent material. A light-emitting layer of the inorganic light-emitting display panel may include a quantum dot and a quantum rod. Hereinafter, it will be exemplified that the display panel DP is an organic light-emitting display panel.

The display panel DP may be a flexible display panel. The display panel DP may extend longer in the first direction DR1 than in the second direction DR2. The display panel DP may include a first portion PP1, a dummy portion DMP, a second portion PP2, a bending area BA, and a third portion PP3.

The first portion PP1, the dummy portion DMP, and the second portion PP2 of the display panel DP may substantially correspond to the first portion PP1, the dummy portion DMP, and the second portion PP2 of the display device DD illustrated in FIG. 5, respectively. Accordingly, the first portion PP1, the dummy portion DMP, and the second portion PP2 of the display panel DP are illustrated using the same reference numerals as the first portion PP1, the dummy portion DMP, and the second portion PP2 of the display device DD. As in the display device DD, the dummy portion DMP may be disposed between the first portion PP1 and the second portion PP2, and the first portion PP1, the dummy portion DMP, and the second portion PP2 may be arranged in the first direction DR1.

The bending area BA may be disposed between the first portion PP1 and the third portion PP3. The bending area BA may extend in the second direction DR2, and the second portion PP2, the dummy portion DMP, the first portion PP1, the bending area BA, and the third portion PP3 may be arranged in the first direction DR1.

The display panel DP may have long sides extending in the first direction DR1 and facing each other in the second direction DR2. The long sides of the display panel DP may be defined by the first portion PP1, the dummy portion DMP, and the second portion PP2. Based on the second direction DR2, the lengths of the bending area BA and the third portion PP3 may be smaller than the lengths of the first portion PP1, the dummy portion DMP, and the second portion PP2.

The dummy portion DMP may include a non-display area NDA. The non-display area NDA may be defined as an area that does not display an image. The first portion PP1 may include a first display area DA1 and a non-display area NDA around the first display area DA1. The non-display area NDA may surround the first display area DA1. The first display area DA1 may be defined as an area that displays an image. The second portion PP2 may include a second display area DA2 and a non-display area NDA around the second display area DA2. The non-display area NDA may surround the second display area DA2. The second display area DA2 may be defined as an area that displays an image. The bending area BA and the third portion PP3 may be defined as areas that do not display an image.

When viewed from above the plane, the sensors SN, the rear cameras BCM, and the front camera FCM may be disposed under the second display area DA2 to overlap the second display area DA2.

When viewed in the second direction DR2, the first portion PP1, the dummy portion DMP, and the second portion PP2 may include a folding area FA and a first non-folding area NFA1 and a second non-folding area NFA2 that are next (adjacent) to the folding area FA. The folding area FA, the first non-folding area NFA1, and the second non-folding area NFA2 of the display panel DP may correspond to the folding area FA, the first non-folding area NFA1, and the second non-folding area NFA2 of the electronic device ED, respectively, which have been described above. Accordingly, the folding area FA may be disposed between the first non-folding area NFA1 and the second non-folding area NFA2, and the first non-folding area NFA1, the folding area FA, and the second non-folding area NFA2 may be arranged in the first direction DR1.

The display panel DP may include a plurality of pixels PX, a plurality of scan lines SL1 to SLm, a plurality of data lines DL1 to DLn, a plurality of light emission lines EL1 to ELM, a first control line CSL1, a second control line CSL2, a first power line PL1, a second power line PL2, a plurality of connecting lines CNL, and a plurality of pads PD. “m” and “n” are natural numbers.

The pixels PX may be disposed in the first display area DA1 and the second display area DA2. The scan driver SDV and the light emission driver EDV may be disposed in the non-display areas NDA next (adjacent) to the long sides of the display panel DP, respectively.

The display panel DP may have short sides extending in the second direction DR2 and facing each other in the first direction DR1.

The data driver DDV may be disposed in the non-display area NDA next (adjacent) to one of the short sides of the display panel DP. The data driver DDV may be next (adjacent) to the lower end of the display panel DP when viewed from above the plane. The data driver DDV may be disposed on the third portion PP3.

The pixels PX that display an image may not be disposed in the dummy portion DMP defined as the non-display area NDA. Accordingly, the dummy portion DMP may not display an image. The scan lines SL1 to SLm, the light emission lines EL1 to ELm, and the data lines DL1 to DLn connected to the pixels PX may pass through the dummy portion DMP.

Although not illustrated, the bending area BA may be bent so that the third portion PP3 may be disposed under the first portion PP1. In this case, the data driver DDV may be disposed under the first portion PP1 and may not be visible from the outside.

The scan lines SL1 to SLm may extend in the second direction DR2 and may be connected to the pixels PX and the scan driver SDV. The data lines DL1 to DLn may extend in the first direction DR1 and may be connected to the pixels PX and the data driver DDV. The light emission lines EL1 to ELm may extend in the second direction DR2 and may be connected to the pixels PX and the light emission driver EDV.

The first power line PL1 may extend in the first direction DR1 and may be disposed in the non-display area NDA. The first power line PL1 may be disposed between the first and second display areas DA1 and DA2 and the light emission driver EDV. However, without being limited thereto, the first power line PL1 may be disposed between the first and second display areas DA1 and DA2 and the scan driver SDV.

The first power line PL1 may extend to the third portion PP3 via the bending area BA. The first power line PL1 may extend toward the lower end of the third portion PP3 when viewed from above the plane. The first power line PL1 may receive a first voltage.

The connecting lines CNL may extend in the second direction DR2 and may be arranged in the first direction DR1 and connected to the first power line PL1 and the pixels PX. The first voltage may be applied to the pixels PX through the first power line PL1 and the connecting lines CNL connected with each other.

The second power line PL2 may be disposed in the non-display area NDA may extend along the long sides of the display panel DP and another short side of the display panel DP where the data driver DDV is not disposed. The second power line PL2 may be disposed outward of the scan driver SDV and the light emission driver EDV.

The second power line PL2 may receive a second voltage having a lower level than a level of the first voltage. Although a connection relationship is not illustrated, the second power line PL2 may extend toward the first display area DA1 and the second display area DA2, and may be connected to the pixels PX. The second voltage having a lower level than a level of the first voltage may be applied to the pixels PX through the second power line PL2.

The first control line CSL1 may be connected to the scan driver SDV and may extend toward the lower end of the display panel DP. The second control line CSL2 may be connected to the light emission driver EDV and may extend toward the lower end of the display panel DP. The data driver DDV may be disposed between the first control line CSL1 and the second control line CSL2.

The pads PD may be disposed in the non-display area NDA next (adjacent) to the lower end of the display panel DP and may be closer to the lower end of the display panel DP than the data driver DDV is to the lower end of the display panel DP. The data driver DDV, the first power line PL1, the second power line PL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Although not illustrated, the display device DD may further include a timing controller for controlling operation of the scan driver SDV, the data driver DDV, and the light emission driver EDV and a voltage generator for generating the first voltage and the second voltage. The timing controller and the voltage generator may be disposed (e.g., mounted) on a printed circuit board and may be connected to the pads PD through the printed circuit board.

The timing controller may control operation of the scan driver SDV, the data driver DDV, and the light emission driver EDV. The timing controller may generate a scan control signal, a data control signal, and a light emission control signal in response to control signals received from the outside.

The scan control signal may be provided to the scan driver SDV through the first control line CSL1. The scan driver SDV may generate a plurality of scan signals in response to the scan control signal. The scan signals may be applied to the pixels PX through the scan lines SL1 to SLm. The scan signals may be sequentially applied to the pixels PX.

The data control signal may be provided to the data driver DDV. The data driver DDV may generate a plurality of data voltages in response to the data control signal, and the data voltages may be applied to the pixels PX through the data lines DL1 to DLn.

The light emission control signal may be provided to the light emission driver EDV through the second control line CSL2. The light emission driver EDV may generate a plurality of light emission signals in response to the light emission control signal, and the light emission signals may be applied to the pixels PX through the light emission lines EL1 to ELm.

The pixels PX may receive the data voltages in response to the scan signals. The pixels PX may display an image by emitting light having luminance corresponding to the data voltages in response to the light emission signals.

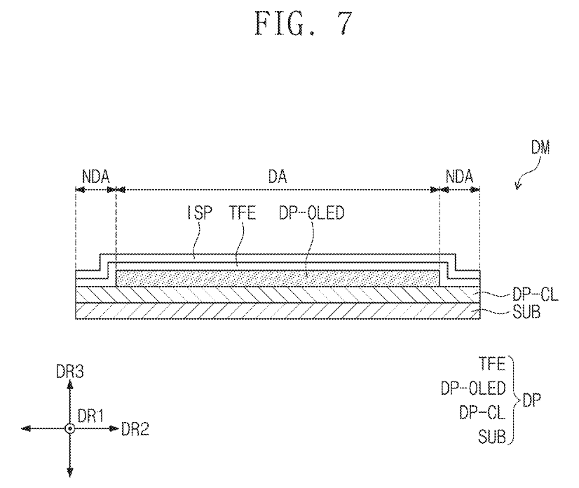

FIG. 7 is a view illustrating a cross-section of the display module used in the display device illustrated in FIG. 5.

In an embodiment, in FIG. 7, a cross-section of the display module DM viewed in the first direction DR1 is illustrated, for example.

Referring to FIG. 7, the display module DM may include the display panel DP that generates an image and an input sensing part ISP that senses an external input. The input sensing part ISP may be disposed on the display panel DP.

The display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include a display area DA and a non-display area NDA around the display area DA. The substrate SUB may include glass or may include a flexible plastic material such as polyimide (“PI”).

The circuit element layer DP-CL may include transistors to be described below.

The display element layer DP-OLED may be disposed on the display area DA. The display element layer DP-OLED may generate an image. The display element layer DP-OLED may include light-emitting elements connected to the transistors. The plurality of pixels PX may be disposed in the circuit element layer DP-CL and the display element layer DP-OLED. Each of the pixels PX may include a transistor disposed in the circuit element layer DP-CL and a light-emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may include an inorganic layer, an organic layer, and an inorganic layer sequentially stacked one above another. The inorganic layers may include an inorganic material and may protect the pixels from moisture/oxygen. The organic layer may include an organic material and may protect the pixels PX from foreign matter such as dust particles.

The input sensing part ISP may be disposed on the display panel DP. The input sensing part ISP may include a plurality of sensing units for sensing an external input in a capacitive type. The input sensing part ISP may be directly manufactured on the display panel DP when the display module DM is manufactured. However, without being limited thereto, the input sensing part ISP may be manufactured as a panel separate from the display panel DP and may be attached to the display panel DP by an adhesive layer.

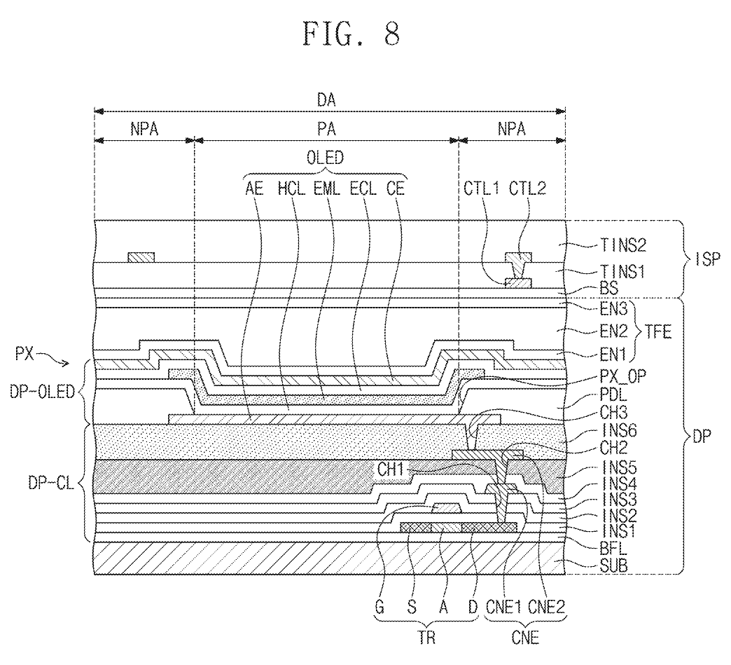

FIG. 8 is a view more specifically illustrating a cross-section of the display panel and the input sensing part corresponding to one pixel illustrated in FIG. 6.

Referring to FIG. 8, the display panel DP may include the pixel PX, and the pixel PX may include a transistor TR and a light-emitting element OLED.

The light-emitting element OLED may be an organic light-emitting element. The light-emitting element OLED may include a first electrode AE (an anode), a second electrode CE (a cathode), a hole control layer HCL, an electron control layer ECL, and a light-emitting layer EML.

The transistor TR and the light-emitting element OLED may be disposed on the substrate SUB. Although one transistor TR is illustrated in an embodiment, substantially, the pixel PX may include a plurality of transistors TR and at least one capacitor for driving the light-emitting element OLED.

A display area DA may include a light-emitting area PA corresponding to each of the pixels PX and a non-light-emitting area NPA around the light-emitting area PA. The light-emitting element OLED may be disposed in the light-emitting area PA.

A buffer layer BFL may be disposed on the substrate SUB. The buffer layer BFL may be an inorganic layer. A semiconductor pattern may be disposed on the buffer layer BFL. The semiconductor pattern may include poly silicon, amorphous silicon, or metal oxide.

The semiconductor pattern may be doped with an N-type dopant or a P-type dopant. The semiconductor pattern may include a highly doped area and a lightly doped area. The highly doped area may have a higher conductivity than a conductivity of the lightly doped area and may substantially serve as a source electrode and a drain electrode of the transistor TR. The lightly doped area may substantially correspond to an active area (or, a channel) of the transistor TR.

The source S, the active area A, and the drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connecting electrode CNE may include a first connecting electrode CNE1 and a second connecting electrode CNE2 to connect the transistor TR and the light-emitting element OLED. The first connecting electrode CNE1 may be disposed on the third insulating layer INS3 and may be connected to the drain D through a first contact hole CH1 defined in the first to third insulating layers INS1 to INS3.

A fourth insulating layer INS4 may be disposed on the first connecting electrode CNE1. A fifth insulating layer INS5 may be disposed on the fourth insulating layer INS4. The second connecting electrode CNE2 may be disposed on the fifth insulating layer INS5. The second connecting electrode CNE2 may be connected to the first connecting electrode CNE1 through a second contact hole CH2 defined in the fourth insulating layer INS4 and the fifth insulating layer INS5.

A sixth insulating layer INS6 may be disposed on the second connecting electrode CNE2. The layers from the buffer layer BFL to the sixth insulating layer INS6 may be defined as the circuit element layer DP-CL. The first to sixth insulating layers INS1 to INS6 may be inorganic layers or organic layers.

The first electrode AE may be disposed on the sixth insulating layer INS6. The first electrode AE may be connected to the second connecting electrode CNE2 through a third contact hole CH3 defined in the sixth insulating layer INS6. A pixel defining layer PDL defining an opening PX_OP therein to expose a predetermined portion of the first electrode AE may be disposed on the first electrode AE and the sixth insulating layer INS6.

The hole control layer HCL may be disposed on the first electrode AE and the pixel defining layer PDL. The hole control layer HCL may include a hole transport layer and a hole injection layer.

The light-emitting layer EML may be disposed on the hole control layer HCL. The light-emitting layer EML may be disposed in the area corresponding to the opening PX_OP. The light-emitting layer EML may include an organic material and/or an inorganic material. The light-emitting layer EML may generate one of red light, green light, and blue light.

The electron control layer ECL may be disposed on the light-emitting layer EML and the hole control layer HCL. The electron control layer ECL may include an electron transport layer and an electron injection layer. The hole control layer HCL and the electron control layer ECL may be commonly disposed in the light-emitting area PA and the non-light-emitting area NPA.

The second electrode CE may be disposed on the electron control layer ECL. The second electrode CE may be commonly disposed in the pixels PX. The layer in which the light-emitting element OLED is disposed may be defined as the display element layer DP-OLED.

The thin film encapsulation layer TFE may be disposed on the second electrode CE and may cover the pixel PX. The thin film encapsulation layer TFE may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first encapsulation layer EN1 and the third encapsulation layer EN3 may include an inorganic insulating layer and may protect the pixel PX from moisture/oxygen. The second encapsulation layer EN2 may include an organic insulating layer and may protect the pixel PX from foreign matter such as dust particles.

The first voltage may be applied to the first electrode AE through the transistor TR, and the second voltage having a lower level than a level of the first voltage may be applied to the second electrode CE. Holes and electrons injected into the light-emitting layer EML may be combined to form excitons, and as the excitons transition to a ground state, the light-emitting element OLED may emit light.

The layers from the substrate SUB to the thin film encapsulation layer TFE may be defined as the display panel DP. The input sensing part ISP may be disposed on the thin film encapsulation layer TFE. The input sensing part ISP may be directly manufactured on the upper surface of the thin film encapsulation layer TFE.

A base layer BS may be disposed on the thin film encapsulation layer TFE. The base layer BS may include an inorganic insulating layer. At least one inorganic insulating layer may be provided as the base layer BS on the thin film encapsulation layer TFE.

The input sensing part ISP may include a first conductive pattern CTL1 and a second conductive pattern CTL2 disposed on the first conductive pattern CTL1. The first conductive pattern CTL1 may be disposed on the base layer BS. A first insulating layer TINS1 may be disposed on the base layer BS to cover the first conductive pattern CTL1. The first insulating layer TINS1 may include an organic insulating layer or an organic insulating layer.

The second conductive pattern CTL2 may be disposed on the first insulating layer TINS1. A second insulating layer TINS2 may be disposed on the first insulating layer TINS1 to cover the second conductive pattern CTL2. The second insulating layer TINS2 may include an organic insulating layer.

The first conductive pattern CTL1 and the second conductive pattern CTL2 may overlap the non-light-emitting area NPA. Although not illustrated, the first conductive pattern CTL1 and the second conductive pattern CTL2 may be disposed on the non-light-emitting area NPA between the light-emitting areas PA and may have a mesh shape.

The first conductive pattern CTL1 and the second conductive pattern CTL2 may form sensors of the input sensing part ISP described above. In an embodiment, the first conductive pattern CTL1 and the second conductive pattern CTL2 having a mesh shape may be separated from each other in a predetermined area to form sensors, for example. A portion of the second conductive pattern CTL2 may be connected to the first conductive pattern CTL1.

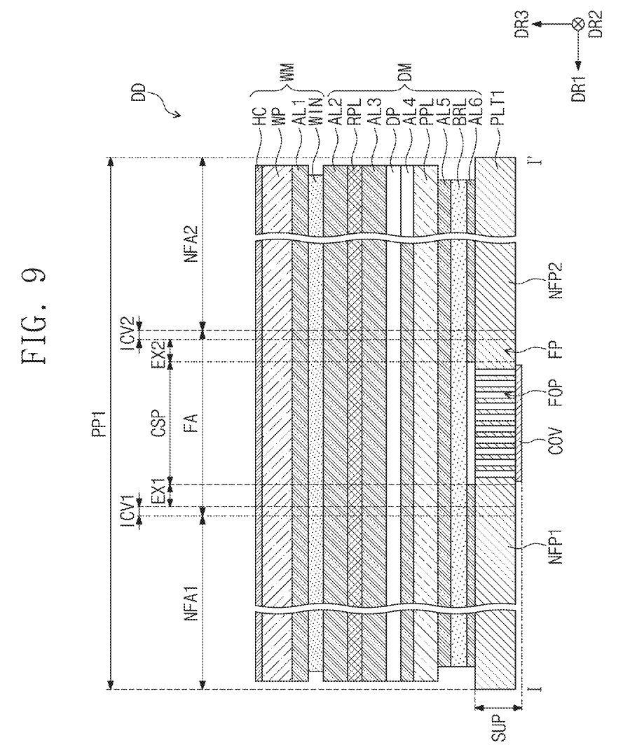

FIG. 9 is a cross-sectional view of the display device corresponding to line I-I’ illustrated in FIG. 6.

Referring to FIG. 9, the display device DD in an embodiment of the disclosure may include a window module WM, the display module DM disposed under the window module WM, and a support part SUP disposed under the display module DM to support the display module DM.

The display module DM may be a flexible display module. The display module DM and the window module WM may include a folding area FA and a first non-folding area NFA1 and a second non-folding area NFA2 that are next (adjacent) to the folding area FA, like the display panel DP described above. Accordingly, in the display module DM and the window module WM, the folding area FA may be disposed between the first non-folding area NFA1 and the second non-folding area NFA2, and the first non-folding area NFA1, the folding area FA, and the second non-folding area NFA2 may be arranged in the first direction DR1.

Hereinafter, detailed components of the window module WM, the display module DM, and the support part SUP will be described based on a flat state of the display device DD.

The window module WM may include a window WIN, a window protection layer WP, a hard coating layer HC, and a first adhesive layer AL1.

The display module DM may include a barrier layer BRL, a panel protection layer PPL, the display panel DP, an anti-reflective layer RPL, and second to sixth adhesive layers AL2 to AL6.

The anti-reflective layer RPL, the window WIN, the window protection layer WP, and the hard coating layer HC may be disposed on the display panel DP. The panel protection layer PPL and the barrier layer BRL may be disposed under the display panel DP.

The anti-reflective layer RPL may be disposed on the display panel DP. The anti-reflective layer RPL may be defined as a film for preventing reflection of external light. The anti-reflective layer RPL may decrease the reflectance of external light incident toward the display panel DP from the outside.

When the external light traveling toward the display panel DP is reflected by the display panel DP and then provided back to the user, the user may visually recognize the external light as in a mirror. To prevent such a phenomenon, e.g., the anti-reflective layer RPL may include a plurality of color filters that display the same colors as the pixels PX.

The color filters may filter the external light in the same colors as the pixels. In this case, the external light may not be visible to the user. However, without being limited thereto, the anti-reflective layer RPL may include a phase retarder and/or a polarizer to decrease the reflectance of the external light.

The window WIN may be disposed on the anti-reflective layer RPL. The window WIN may protect the display panel DP and the anti-reflective layer RPL from external scratches. The window WIN may have a property of being optically clear. The window WIN may include glass. However, without being limited thereto, the window WIN may include a synthetic resin film.

The window WIN may have a single-layer structure or a multi-layer structure. In an embodiment, the window WIN may include a plurality of synthetic resin films coupled through an adhesive or may include a glass substrate and a synthetic resin film coupled through an adhesive, for example.

The window protection layer WP may be disposed on the window WIN. The window protection layer WP may include a flexible plastic material such as polyimide or polyethylene terephthalate (“PET”).

The hard coating layer HC may be disposed on the upper surface of the window protection layer WP.

The first adhesive layer AL1 may be disposed between the window protection layer WP and the window WIN. The window protection layer WP and the window WIN may be bonded to each other by the first adhesive layer AL1.

The second adhesive layer AL2 may be disposed between the window WIN and the anti-reflective layer RPL. The window WIN and the anti-reflective layer RPL may be bonded to each other by the second adhesive layer AL2.

The third adhesive layer AL3 may be disposed between the anti-reflective layer RPL and the display panel DP. The anti-reflective layer RPL and the display panel DP may be bonded to each other by the third adhesive layer AL3.

The panel protection layer PPL may be disposed under the display panel DP. The panel protection layer PPL may protect the bottom of the display panel DP. The panel protection layer PPL may include a flexible plastic substrate. In an embodiment, the panel protection layer PPL may include polyethylene terephthalate, for example.

The barrier layer BRL may be disposed under the panel protection layer PPL. The barrier layer BRL may increase resistance to a compressive force caused by external pressing. Accordingly, the barrier layer BRL may serve to prevent deformation of the display panel DP. The barrier layer BRL may include a flexible plastic material such as polyimide or polyethylene terephthalate.

The barrier layer BRL may have a color that absorbs light. The barrier layer BRL may have a black color. In this case, components disposed under the barrier layer BRL may not be visible when the display module DM is viewed from above the plane.

The fourth adhesive layer AL4 may be disposed between the display panel DP and the panel protection layer PPL. The display panel DP and the panel protection layer PPL may be bonded to each other by the fourth adhesive layer AL4.

The fifth adhesive layer AL5 may be disposed between the panel protection layer PPL and the barrier layer BRL. The panel protection layer PPL and the barrier layer BRL may be bonded to each other by the fifth adhesive layer AL5.

The sixth adhesive layer AL6 may be disposed under the barrier layer BRL. The sixth adhesive layer AL6 may be disposed between the barrier layer BRL and a first support plate PLT1 of the support part SUP. The barrier layer BRL and the first support plate PLT1 may be bonded to each other by the sixth adhesive layer AL6.

The first to sixth adhesive layers AL1 to AL6 may include a transparent adhesive, such as a pressure sensitive adhesive (“PSA”) or an optically clear adhesive (“OCA”), but the type of adhesive is not limited thereto.

The panel protection layer PPL may have a smaller thickness than a thickness of the window protection layer WP, the anti-reflective layer RPL may have a smaller thickness than a thickness of the panel protection layer PPL, and the display panel DP may have a smaller thickness than a thickness of the anti-reflective layer RPL. The window WIN may have the same thickness as the anti-reflective layer RPL. The barrier layer BRL may have a smaller thickness than a thickness of the panel protection layer PPL and may have a greater thickness than a thickness of the anti-reflective layer RPL.

The first adhesive layer AL1 may have the same thickness as the barrier layer BRL, and the second adhesive layer AL2 and the third adhesive layer AL3 may have the same thickness as the panel protection layer PPL. Each of the fourth adhesive layer AL4 and the fifth adhesive layer AL5 may have a smaller thickness than a thickness of the display panel DP. The fourth adhesive layer AL4 and the fifth adhesive layer AL5 may have the same thickness. The sixth adhesive layer AL6 may have a smaller thickness than a thickness of the fourth adhesive layer AL4 and the fifth adhesive layer AL5, and the hard coating layer HC may have a smaller thickness than a thickness of the sixth adhesive layer AL6.

The display panel DP, the anti-reflective layer RPL, the panel protection layer PPL, and the second to fourth adhesive layers AL2 to AL4 may have the same width.

The window protection layer WP, the hard coating layer HC, and the first adhesive layer AL1 may have the same width.

The window WIN may have a smaller width than a width of the display panel DP, the anti-reflective layer RPL, the panel protection layer PPL, and the second to fourth adhesive layers AL2 to AL4. In addition, the window WIN may have a smaller width than a width of the window protection layer WP, the hard coating layer HC, and the first adhesive layer AL1.

When viewed from above the plane, the border of the window WIN may be disposed inward of the borders of the display panel DP, the anti-reflective layer RPL, the panel protection layer PPL, and the second to fourth adhesive layers AL2 to AL4. In addition, when viewed from above the plane, the border of the window WIN may be disposed inward of the borders of the window protection layer WP, the hard coating layer HC, and the first adhesive layer AL1.

When viewed from above the plane, the barrier layer BRL may have the same width as the fifth adhesive layer AL5 and the sixth adhesive layer AL6. When viewed from above the plane, the borders of the barrier layer BRL, the fifth adhesive layer AL5, and the sixth adhesive layer AL6 may be disposed inward of the border of the window WIN.

The support part SUP may include the first support plate PLT1 and a cover layer COV.

The first support plate PLT1 may be disposed under the display module DM to support the display module DM. The first support plate PLT1 may have a higher rigidity than a rigidity of the display module DM. Openings FOP overlapping the folding area FA may be defined in the first support plate PLT1.

The first support plate PLT1 may include a metallic material such as stainless steel. In an embodiment, the first support plate PLT1 may include SUS304, for example. However, without being limited thereto, the first support plate PLT1 may include various metallic materials. In addition, without being limited thereto, the first support plate PLT1 may include a non-metallic material such as glass or plastic.

The first support plate PLT1 may include a first non-folding portion NFP1, a folding portion FP, and a second non-folding portion NFP2. In an embodiment, the boundaries between the first non-folding portion NFP1, the folding portion FP, and the second non-folding portion NFP2 are illustrated by dotted lines on the first support plate PLT1, for example. The first non-folding portion NFP1, the folding portion FP, and the second non-folding portion NFP2 may be arranged in the first direction DR1. The folding portion FP may be disposed between the first non-folding portion NFP1 and the second non-folding portion NFP2. The openings FOP may be defined in the folding portion FP.

The first non-folding portion NFP1 may be disposed under the first non-folding area NFA1 and may overlap the first non-folding area NFA1. The second non-folding portion NFP2 may be disposed under the second non-folding area NFA2 and may overlap the second non-folding area NFA2. The folding portion FP may be disposed under the folding area FA and may overlap the folding area FA. The folding portion FP may be folded when the display device DD is folded. A folded state of the folding portion FP will be described below in detail with reference to FIG. 12.

The folding portion FP may include a curved portion CSP, a first extension EX1, a second extension EX2, a first reverse curvature portion ICV1, and a second reverse curvature portion ICV2. In an embodiment, the boundaries between the curved portion CSP, the first extension EX1, the second extension EX2, the first reverse curvature portion ICV1, and the second reverse curvature portion ICV2 are illustrated by dotted lines on the first support plate PLT1, and for convenience, the reference numerals thereof are illustrated over the window module WM, with the dotted boundary lines extended upward, for example.

The curved portion CSP, the first extension EX1, the second extension EX2, the first reverse curvature portion ICV1, and the second reverse curvature portion ICV2 may be arranged in the first direction DR1. In an embodiment, the curved portion CSP may be disposed at the center of the folding portion FP, for example.

The curved portion CSP may be disposed between the first extension EX1 and the second extension EX2. The openings FOP may be defined in the curved portion CSP. Since the openings FOP are defined in the curved portion CSP, the flexibility of the curved portion CSP may be increased. In this case, the curved portion CSP may be easily folded when the folding portion FP is folded. A folded state of the curved portion CSP will be described below in detail with reference to FIG. 12.

The sixth adhesive layer AL6 may not overlap the curved portion CSP. That is, the sixth adhesive layer AL6 may be open in the area overlapping the curved portion CSP.

The first extension EX1 may be disposed between the first reverse curvature portion ICV1 and the curved portion CSP. The second extension EX2 may be disposed between the second reverse curvature portion ICV2 and the curved portion CSP.

The first reverse curvature portion ICV1 may be disposed between the first extension EX1 and the first non-folding portion NFP1. The second reverse curvature portion ICV2 may be disposed between the second extension EX2 and the second non-folding portion NFP2.

The cover layer COV may be disposed under the first support plate PLT1. The cover layer COV may overlap the first non-folding portion NFP1, the curved portion CSP, and the second non-folding portion NFP2. The cover layer COV may cover the openings FOP, which are defined in the curved portion CSP, from below the curved portion CSP.

The cover layer COV may not overlap the first extension EX1, the first reverse curvature portion ICV1, the second extension EX2, and the second reverse curvature portion ICV2.

The cover layer COV may have a lower elastic modulus than an elastic modulus of the first support plate PLT1. In an embodiment, the cover layer COV may include thermoplastic polyurethane or rubber, but the material of the cover layer COV is not limited thereto, for example. The cover layer COV may be manufactured in a sheet shape and may be attached to the first support plate PLT1.

The width of the first support plate PLT1 may be greater than the width of the window module WM and the width of the display module DM. When viewed from above the plane, the borders of the window module WM and the display module DM may be disposed inward of the border of the first support plate PLT1.

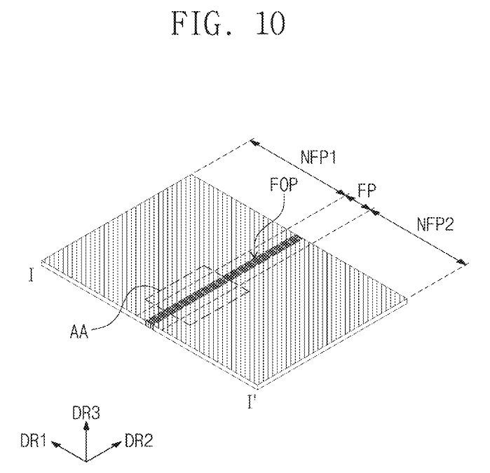

FIG. 10 is a perspective view of the first support plate illustrated in FIG. 9.

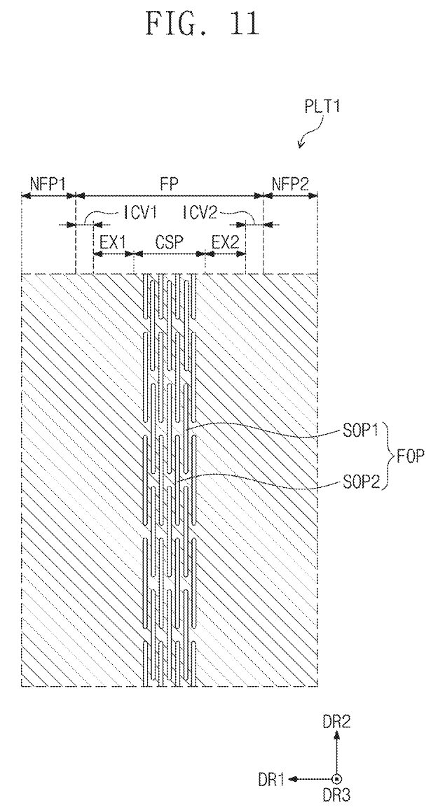

FIG. 11 is an enlarged plan view of area AA illustrated in FIG. 10.

Referring to FIGS. 10 and 11, the first support plate PLT1 may include the first non-folding portion NFP1, the folding portion FP, and the second non-folding portion NFP2 arranged in the first direction DR1. The folding portion FP may include the first reverse curvature portion ICV1, the first extension EX1, the curved portion CSP, the second extension EX2, and the second reverse curvature portion ICV2 arranged in the first direction DR1.

A grid pattern may be defined in the curved portion CSP. In an embodiment, the openings FOP defined in the curved portion CSP may be arranged according to a predetermined rule, for example. The openings FOP may be arranged in a grid shape to form the grid pattern of the curved portion CSP.

The openings FOP may extend longer in the second direction DR2 than in the first direction DR1. The openings FOP may include a plurality of first sub-openings SOP1 arranged in the second direction DR2 and a plurality of second sub-openings SOP2 next (adjacent) to the first sub-openings SOP1 in the first direction DR1 and arranged in the second direction DR2. The first sub-openings SOP1 may be staggered with respect to the second sub-openings SOP2.

FIG. 12 is a view illustrating a folded state of the display device illustrated in FIG. 9.

In an embodiment, in FIG. 12, the display module DM is illustrated as a single layer, for example. In addition, for convenience of description, the first support plate PLT1 is illustrated together with the display module DM, and other components are omitted.

Referring to FIG. 12, the first support plate PLT1 may be folded about the folding axis FX. The first support plate PLT1 may be folded in a dumbbell shape. As the first support plate PLT1 is folded, the display module DM may be folded together with the first support plate PLT1.

The folding portion FP may be folded about the folding axis FX so that the first support plate PLT1 may be folded. When the folding portion FP is folded, the curved portion CSP may be bent to have a predetermined curvature. The curved portion CSP may be bent to have a radius of curvature Rc. The folding area FA may be folded depending on the folding of the folding portion FP.

The first reverse curvature portion ICV1 may be bent opposite to the curved portion CSP. The second reverse curvature portion ICV2 may be bent opposite to the curved portion CSP. The second reverse curvature portion ICV2 may have a shape symmetrical to that of the first reverse curvature portion ICV1.

When the folding portion FP is folded, the first non-folding portion NFP1 and the second non-folding portion NFP2 may remain flat. Accordingly, the first non-folding area NFA1 and the second non-folding area NFA2 may be maintained in a flat state by the first non-folding portion NFP1 and the second non-folding portion NFP2.

When the folding portion FP is folded, the distance between the first non-folding portion NFP1 and the second non-folding portion NFP2 in the first direction DR1 may be smaller than the diameter of the circle having the radius of curvature Rc. Depending on this configuration, the first support plate PLT1 may be folded in a dumbbell shape.

The first extension EX1 may remain flat between the curved portion CSP and the first reverse curvature portion ICV1. The second extension EX2 may remain flat between the curved portion CSP and the second reverse curvature portion ICV2.

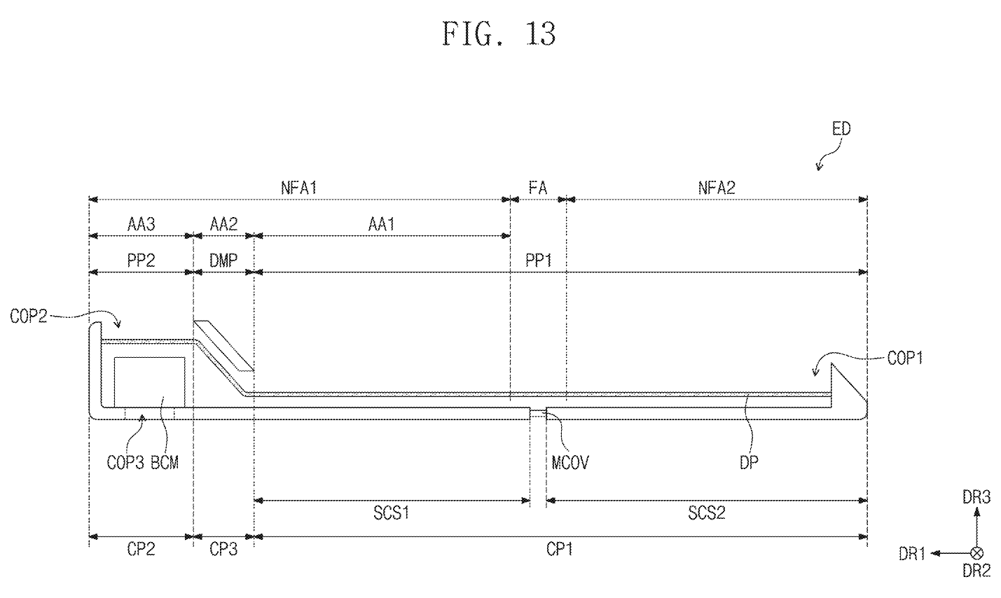

FIG. 13 is a cross-sectional view of the electronic device corresponding to line II-II’ illustrated in FIG. 3.

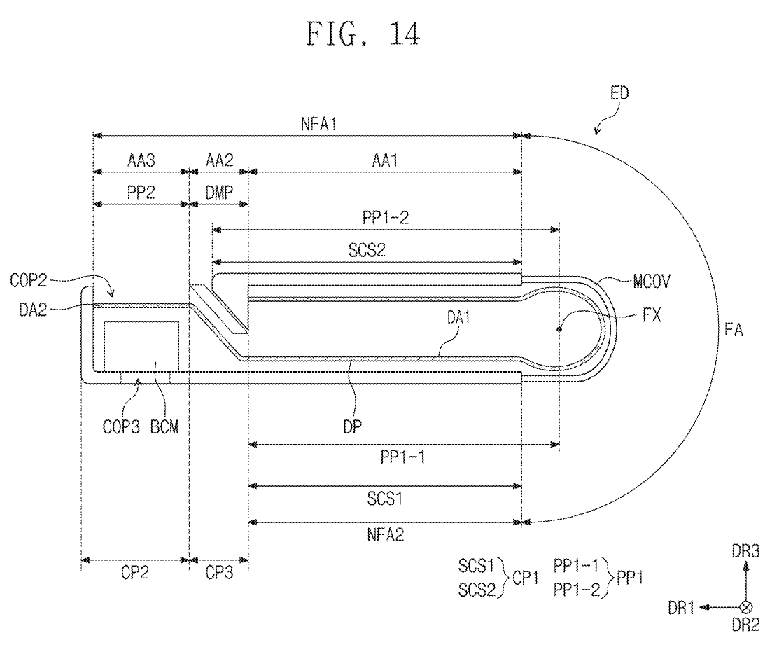

FIG. 14 is a cross-sectional view of the electronic device corresponding to line III-III’ illustrated in FIG. 4.

Referring to FIGS. 13 and 14, the first portion PP1 and the first case portion CP1 may be folded and unfolded about the folding axis FX defined in a direction parallel to the second direction DR2.

Hereinafter, in FIGS. 13 and 14, the display panel DP is illustrated as a single layer. In addition, for convenience of description, the display panel DP, the rear cameras BCM, the case CAS (refer to FIG. 5), and a center cover MCOV are illustrated, and remaining (the other) components are omitted. In an embodiment, unlike in FIG. 5, the display panel DP accommodated in the case CAS (refer to FIG. 5) is illustrated in FIGS, for example. 13 and 14. The rear cameras BCM may be two or more rear cameras BCM. The rear cameras BCM may overlap each other when viewed in the second direction DR2.

The first portion PP1 may include the first-first portion PP1-1 and the first-second portion PP1-2. The first-first portion PP1-1 and the first-second portion PP1-2 may be distinguished from each other based on the folding axis FX. When the first portion PP1 is folded, the first-first portion PP1-1 and the first-second portion PP1-2 may face each other.

The electronic device ED may include the display panel DP and the case CAS that accommodates the display panel DP. The electronic device ED may include the first non-folding area NFA1, the folding area FA, and the second non-folding area NFA2. The first non-folding area NFA1 may include the first area AA1, the second area AA2, and the third area AA3. The first area AA1, the second area AA2, and the third area AA3 may be arranged in the first direction DR1. The configuration of the display panel DP has been described above in detail, and therefore detailed description thereof will be omitted.

The display panel DP may include the first portion PP1, the second portion PP2, and the dummy portion DMP. The first portion PP1, the second portion PP2, and the dummy portion DMP may correspond to the first portion PP1, the second portion PP2, and the dummy portion DMP of the display device DD illustrated in FIG. 6, respectively. When viewed from above the plane, the second portion PP2 and the dummy portion DMP may overlap the first non-folding area NFA1. When viewed from above the plane, the first portion PP1 may overlap a partial area of the first non-folding area NFA1, the folding area FA, and the second non-folding area NFA2.

The case CAS may include the first case portion CP1, the second case portion CP2, and the third case portion CP3. The first case portion CP1, the third case portion CP3, and the second case portion CP2 may be arranged in the first direction DR1. The first case portion CP1 may include the first sub-case portion SCS1 and the second sub-case portion SCS2. When the first case portion CP1 is folded, the first sub-case portion SCS1 and the second sub-case portion SCS2 may face each other.

As described above, the first opening COP1 may be defined in the first case portion CP1, and the second opening COP2 and the third opening COP3 may be defined in the second case portion CP2.

As described above, when viewed from above the plane, the first portion PP1 may overlap the first case portion CP1, the second portion PP2 may overlap the second case portion CP2, and the dummy portion DMP may overlap the third case portion CP3. In addition, the first portion PP1, the second portion PP2, and the dummy portion DMP may be accommodated in the first case portion CP1, the second case portion CP2, and the third case portion CP3, respectively.

In a folding operation of the electronic device ED, the first-first portion PP1-1 and the second sub-case portion SCS2 may overlap a partial area of the dummy portion DMP when viewed from above the plane.

When the first case portion CP1 is folded so that the first sub-case portion SCS1 and the second sub-case portion SCS2 face each other, the first portion PP1 may be folded in a dumbbell shape. The dummy portion DMP may be bent from the first portion PP1 and the second portion PP2 and may be accommodated in the third case portion CP3. When viewed in the second direction DR2, the dummy portion DMP may be bent from the first portion PP1 and the second portion PP2 such that the second portion PP2 is disposed in a higher position than a position of the first portion PP1.

The rear cameras BCM may be disposed in the spaces defined in the second case portion CP2. When viewed in the second direction DR2, the thickness of the side surface of the second case portion CP2 may be greater than the thickness of the side surface of the first case portion CP1. Accordingly, spaces for accommodating the rear cameras BCM may be sufficiently secured in the second case portion CP2. As a result, the rear cameras BCM may be sufficiently accommodated in the second case portion CP2 and thus may not protrude outward.

The center cover MCOV may be disposed between the first sub-case portion SCS1 and the second sub-case portion SCS2. The center cover MCOV may cover the folding area FA of the first portion PP1 of the display panel DP.

As described above, the upper surface of the third case portion CP3 may have an inclined surface, the height of which is gradually increased toward the second case portion CP2 from the first case portion CP1. When the first case portion CP1 is folded, one side of the second sub-case portion SCS2 may face the inclined surface of the third case portion CP3.

In an embodiment of the disclosure, the first portion PP1 may be defined as a main area, and the second portion PP2 may be defined as a sub-area.

When a display panel DP for the main area and a display panel DP for the sub-area are separately used, two display panels DP may be used, and drivers for driving the two display panels DP may be separately used. Therefore, the manufacturing cost of the electronic device ED may be increased. In an embodiment of the disclosure, the main area and the sub-area may be implemented with a single display panel DP. Thus, the manufacturing cost of the electronic device ED may be decreased.

The rear cameras BCM may be exposed to the outside through the third openings COP3 and may take an external image. The rear cameras BCM may be sufficiently disposed in the inner space of the second case portion CP2 having a thicker side surface. Accordingly, the rear cameras BCM may not protrude outward from the lower surface of the second case portion CP2.

Since the rear cameras BCM do not protrude outward, the rear cameras BCM may be sufficiently protected when the electronic device ED receives impacts such as a drop impact.

In an embodiment of the disclosure, the second portion PP2 may be implemented with a transparent display panel. In addition, a transparent case may be disposed on the second portion PP2. In this case, the rear cameras BCM disposed under the second portion PP2 may be visible to the user through the transparent case and the transparent second portion PP2.

In the embodiments of the disclosure, two display panels for implementing the main area and the sub-area may not be used, and the main area and the sub area may be implemented by the single display panel. Accordingly, drivers for driving the two display panels may not be used, and a driver for driving the single display panel may be used. Thus, the manufacturing cost may be reduced.

In the embodiments of the disclosure, the sub-area may be disposed in a higher position than a position of the main area, and the functional elements may be disposed in the space below the sub-area. The space for placing the functional elements may be sufficiently secured so that the functional elements may not protrude outward from the case. Thus, the functional elements may be protected.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. An electronic device comprising:
a display device including:
a first portion;
a second portion; and
a dummy portion disposed between the first portion and the second portion; and
a case which accommodates the display device and in which openings exposing a first display area of the first portion and a second display area of the second portion to the outside are defined,
wherein the dummy portion is bent from the first portion and the second portion,
wherein the first portion is folded and unfolded, and
wherein the second portion is disposed in a higher position than a position of the first portion when the first portion is unfolded.

2. The electronic device of claim 1, wherein the first portion has a larger area than an area of the second portion.

3. The electronic device of claim 1, wherein the case includes:
a first case portion which accommodates the first portion and is configured to be folded and unfolded and in which a first opening defined exposing the first display area is defined; and
a second case portion configured to accommodate the second portion, the second case portion having a second opening defined therein to expose the second display area.

4. The electronic device of claim 3, wherein the first portion and the first case portion are folded and unfolded about a folding axis, and when viewed in a direction parallel to the folding axis, a side surface of the second case portion has a greater thickness than a thickness of a side surface of the first case portion.

5. The electronic device of claim 3, further comprising:
a functional element disposed inside the second case portion.

6. The electronic device of claim 5, wherein a third opening configured to expose the functional element is defined in a lower surface of the second case portion.

7. The electronic device of claim 5, wherein the functional element does not protrude outward from a lower surface of the second case portion.

8. The electronic device of claim 5, wherein the functional element is disposed under the second portion.

9. The electronic device of claim 3, wherein the case further includes a third case portion configured to accommodate the dummy portion and disposed between the first case portion and the second case portion.

10. The electronic device of claim 9, wherein the third case portion closes the dummy portion.

11. The electronic device of claim 9, wherein the dummy portion does not display an image.

12. The electronic device of claim 9, wherein an upper surface of the third case portion has an inclined surface.

13. The electronic device of claim 12, wherein a height of the inclined surface is gradually increased toward the second case portion from the first case portion.

14. The electronic device of claim 12, wherein one side of the first case portion faces the inclined surface of the third case portion when the first case portion is folded.

15. An electronic device comprising:
a display device including:
a first portion;
a second portion; and
a dummy portion disposed between the first portion and the second portion; and
a case which accommodates the display device and in which openings exposing a first display area of the first portion and a second display area of the second portion to the outside are defined, the case including:
a first case portion which accommodates the first portion and configured to be folded and unfolded and in which a first opening exposing the first display area is defined;
a second case portion which accommodates the second portion and in which a second opening which exposes the second display area is defined; and
a third case portion which accommodates the dummy portion and is disposed between the first case portion and the second case portion, and
wherein the dummy portion is closed by the third case portion.

16. The electronic device of claim 15, wherein the first portion and the first case portion are folded and unfolded about a folding axis, and in a direction parallel to the folding axis, a side surface of the second case portion has a greater thickness than a thickness of a side surface of the first case portion.

17. The electronic device of claim 15, further comprising:
a functional element disposed inside the second case portion.

18. The electronic device of claim 17, wherein a third opening configured to expose the functional element is defined in a lower surface of the second case portion.

19. The electronic device of claim 17, wherein the functional element does not protrude outward from a lower surface of the second case portion.

20. The electronic device of claim 15, wherein an upper surface of the third case portion has an inclined surface, and
wherein one side of the first case portion faces the inclined surface of the third case portion when the first case portion is folded.
